(19) United States
(12) Patent Application Publication
(10) Pub. No.: US 2009/0142875 A1
(43) Pub. Date: Jun. 4, 2009

(54) METHOD OF MAKING AN IMPROVED SELECTIVE EMITTER FOR SILICON SOLAR CELLS

(75) Inventors: Peter Borden, San Mateo, CA (US); Mitchell C. Taylor, Lake Oswego, OR (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 11/948,630

(22) Filed: Nov. 30, 2007

(51) Int. Cl. H01L 31/18; H01L 21/26

(52) U.S. Cl. 438/69; 438/513; 257/E21.328; 257/E31.001

(57) ABSTRACT

A method for forming a selective emitter on a silicon solar cell is provided including forming an oxide layer on a surface of the P-type silicon substrate, implanting phosphorus doping atoms into the oxide layer on the substrate using plasma immersion ion implantation, patterning the oxide layer, annealing the substrate to provide heavily doped regions in the patterned regions and a lightly doped region between the patterned regions, and providing metal contacts to the heavily doped regions.

### FIELD OF THE INVENTION

This invention pertains generally to silicon solar cells and improvements to their manufacture directed to improve the electrical and optical performance, more specifically, the invention pertains to the formation of a selective emitter utilizing improved processing techniques.

### BACKGROUND OF THE INVENTION

Multi-crystalline silicon or single crystal silicon is used for the semiconductor substrate in the manufacture of silicon solar cells. Optimal solar cell performance depends on maximum absorption of light, minimized recombination, and minimized contact resistance at the junction between the crystalline semiconductor portion of the cell and the metal contacts used to collect charges and route current outside the cell.

Typically such silicon solar cells are formed utilizing a P-type substrate material with an N-type region, typically one micron thick, formed on the front surface thereof with diffused phosphorous. This forms the emitter of the solar cell. The dopant concentration in the phosphorous doped emitter is relatively low which improves junction characteristics but makes it difficult to form a low resistance contact to the layer. Efforts have been made to selectively engineer the doping profile of solar cells so as to derive maximum benefit from phosphorous doping in the region of contact metallization while minimizing doping between contacts. This selectively patterned emitter doping profile (selective emitter) has historically been obtained by using lithographic or screen printed alignment techniques and multiple high temperature diffusion steps. This selectively patterned emitter doping profile provides regions under the metal contacts which are heavily doped while the emitter is lightly doped between the contacts. However, the prior art processes utilized to accomplish this selectively patterned emitter doping profile using the lithographic or screen printing processing is costly and therefore undesirable.

A need exists, therefore, for a cost and energy efficient technology that permits selectively doping the emitter profile of silicon solar cells which is compatible with commonly employed methods of solar cell manufacture.

### BRIEF SUMMARY OF THE INVENTION

The method of forming a selective emitter in accordance with the principles of the present invention includes forming a thin oxide layer on the surface of the silicon substrate, implanting phosphorous into the oxide utilizing a plasma immersion process forming an anti-reflective coating over the oxide, patterning the oxide to provide openings therein, providing plasma immersion ion implantation of phosphorous into the substrate through the openings provided in the oxide layer, annealing the substrate to drive the ion implanted phosphorous into the substrate to provide heavily doped regions and then providing metal contacts to the heavily doped regions. At the same time, the annealing causes the implanted phosphorous contained in the oxide layer to diffuse into the substrate to form a lightly doped phosphorous region between the heavily doped areas where the metal contacts are formed.

### BRIEF DESCRIPTION OF THE DRAWINGS

FIG. 1 is a process flowchart used in the prior art;

FIG. 2 is a process flowchart illustrative of the steps used in the present invention;

FIG. 3 is a schematic illustration of one embodiment of the invention;

FIG. 4 is a flowchart showing another embodiment of the process steps of the present invention;

FIG. 5 is a schematic illustration showing plasma doping through a mask in accordance with an embodiment of the method of the present invention; and

FIG. 6 is a flowchart showing the steps involved using the apparatus illustrated in FIG. 5.

### DETAILED DESCRIPTION

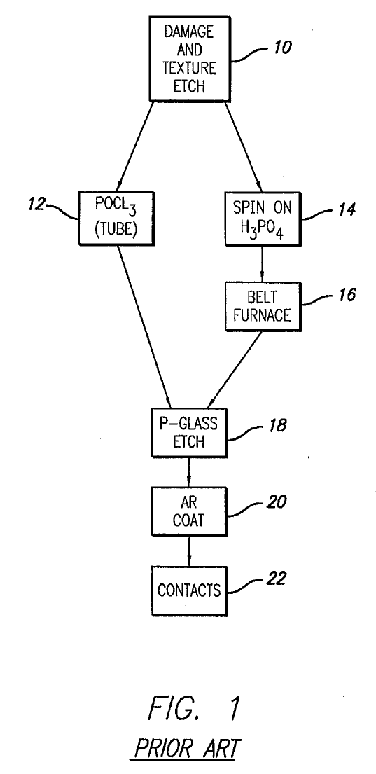

Referring now more particularly to FIG. 1, there is shown the traditional steps utilized in the processing of silicon solar cells. As is therein shown, the substrates which are formed of single-crystalline or multi-crystalline silicon wafers are etched as shown at 10 to eliminate damage which may be done at the time the wafer is formed. An etch done concurrently or immediately after the damage etch is also utilized to texture the surface of the substrate as is well known in the prior art. Subsequent to the damage plus the texture etch, the front surface of the substrate is processed to form an N-type layer in the P-type substrate. This is typically accomplished by applying a phosphorus compound such as a POCl₃ layer on the front surface of the substrate and then diffusing the phosphorus from that layer into the surface of the substrate in a tube furnace as is shown at 12. Alternatively, the phosphorus may be applied to the front surface of the substrate by a spin-on process utilizing H₃PO₄ as is shown at 14. When this occurs, the wafer with the layer of H₃PO₄ is then inserted into a belt furnace 16 to cause the phosphorus to diffuse into the front surface of the substrate.

In either of these processes, a phospho-silicate glass is formed on the surface of the substrate. As a result, this P-glass must be removed from the surface and such is done by etching the surface with an appropriate etch to remove the P-glass. Thereafter, an anti-reflective coating as well known in the art is applied as shown at 20, after which the appropriate metal contacts are applied to the surface of the solar cell for collecting the current generated by the photovoltaic activity of the solar cell.

An additional process to accomplish doping of silicon substrates to provide the N-type layer is by ion implantation which has traditionally been done utilizing the appropriate magnets and controls associated therewith to generate the required ion energy to cause the phosphorus dopant to penetrate the surface of the silicon substrate. This process is very expensive to accomplish and normally is not used in production. In addition, damage is imparted to the surface of the substrate by the high-energy ions striking the silicon. Such damage creates recombination centers at the surface of the wafer, resulting in a poor lifetime.

In accordance with principles of the invention, the phosphorus doping material is applied to the silicon substrate through the utilization of a process referred to as plasma immersion ion implantation (P3i). Although the implantation of phosphorus is referred to above, it should be understood that if a P-type region is to be formed in an N-type body, boron may be used as the dopant or alternatively arsenic may be used in place of or with phosphorus. Typically, in utilizing the P3i process, a gas including hydrogen plus phosphine in the range of 0.5% or diborane in the range of 0.5% may be flowed into the interior of a chamber within which a plasma can be generated. Such chambers are well known in the prior art and typically are referred to as plasma enhanced chemical vapor deposition (PECVD) chambers. In utilizing the P3i system in accordance with principles of the present invention, a bias is applied to the silicon substrate to accelerate the doping ions generated in the plasma into the wafer.

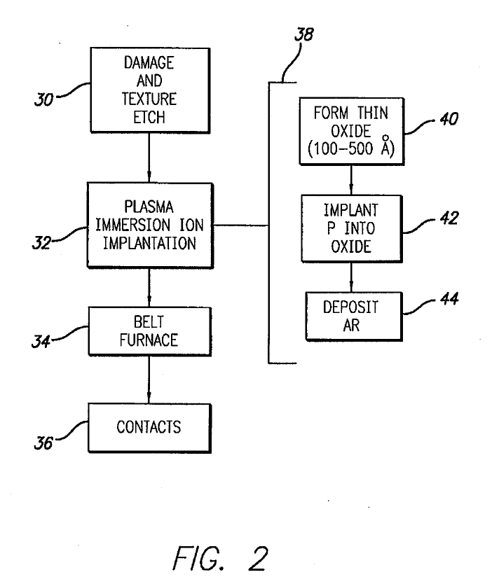

For purposes of further description of the principles of the present invention, reference is made to FIG. 2, which will be limited, for purposes of the example only, to the discussion of implanting phosphorus ions into the surface of a silicon substrate. As is illustrated in FIG. 2, the damage plus texture etch is performed on the silicon substrate for the reasons above set forth. Thereafter, the appropriately etched silicon substrate is placed within a chamber which is adapted to generate an appropriate plasma for accomplishing the plasma immersion ion implantation as shown at 32. After the plasma immersion ion implantation is accomplished, the substrate with the phosphorus ions implanted in the front surface thereof is inserted into a belt furnace 34 to cause the phosphorus doping ions to diffuse into the front surface of the substrate to form the shallow N-type junction in the P-type body. Thereafter, the appropriate contacts are applied as shown at 36. The P3i process is further defined as shown in FIG. 2 as including the steps contained in the bracket 38. As is therein shown, a thin passivating oxide layer, such as SiO₂ is applied, which will have a thickness of approximately 100-500 Angstroms. This may be accomplished within the same chamber as the chamber in which the plasma is to be generated by flowing a gas comprising H₂O₂ and thereafter utilizing a chemical vapor deposition of the SiO₂ from silane or the like to accomplish the desired thickness. Thereafter, the mixture of hydrogen plus phosphine (0.5%) is inserted into the chamber and the appropriate plasma is generated as is well known in the prior art. As a result of the plasma and the biasing of the substrate, the phosphorus ions generated in the plasma are implanted into the thin oxide layer in an amount sufficient to provide the desired N-type region across the front surface of the P-type substrate. As is shown at 42, thereafter and within the same chamber in which the plasma is generated, an appropriate AR coating such as SiNx is applied over the passivating SiOx as shown at 44. The antireflective coating such as SiNx may be applied in the same chamber as the P3i is performed. The AR coating will also function as a cap on the passivation SiOx layer, thus preventing the implanted phosphorus ions from out-diffusing when the substrate is placed in the belt furnace 34. It will also be recognized by those skilled in the art that, by utilizing the P3i process, ion implantation of the phosphorus dopant is accomplished without damage of any type to the silicon substrate. In addition to the foregoing, the depth of diffusion of the phosphorus doping atoms into the silicon substrate can be controlled by selecting the proper temperature and time to obtain the desired parameters for the N-type layer. For example, the substrate with the doped oxide layer may be subjected to a temperature of approximately 850° C. for thirty minutes to obtain the desired depth of diffusion of the phosphorus doping atoms.

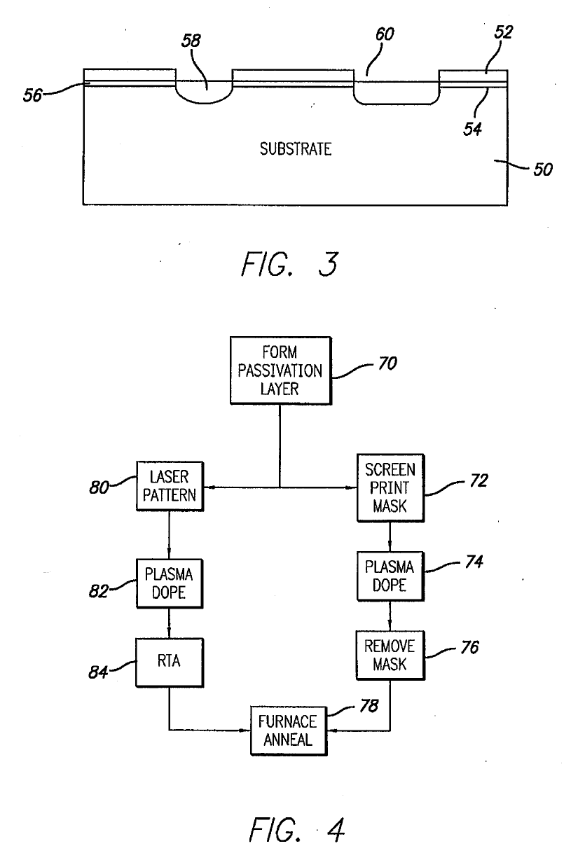

As above referred to, in order to obtain the desired low resistance contact for the top grid contacts, the area immediately beneath the grid must be heavily doped, but at the same time the N-type layer between the contacts should be lightly doped to provide the best performance characteristics of the silicon solar cell. Such a structure is illustrated in FIG. 3, to which reference is hereby made. As is therein shown, a P-type silicon substrate 50 includes at the upper surface thereof a passivating layer 52 such as a thin SiOx layer as above described. Immediately beneath the layer is a PN junction 54 formed by the N-type layer 56 accomplished by diffusing the phosphorus doping atoms from the passivating layer 56 into the upper surface of the substrate. A highly doped region 58 is formed in the upper surface of the substrate 50 and it is to this area that the contact grids are connected. This provides the low resistance region for contact to the substrate 50. The highly doped region 58 is provided by generating a pattern of open regions such as shown at 60 in the passivating layer 52. After formation of the patterned area, which may be accomplished through the utilization of laser ablation or screen printing a mask, etching and removing the mask at some later time.

It should also be recognized that the substrate with the passivating layer 52 having the phosphorus dopant atoms contained therein as a result of the P3i process above-described, may have the patterned openings 60 formed therein and subsequent to the formation of the openings 60, the substrate may be again placed in a chamber within which a plasma can be generated utilizing the above-referred to P3i process. When such is accomplished, the passivating layer 52 will function as a mask which will block most of the P3i ions, but in the area where the passivating oxide layer has been removed, the phosphorus ions will penetrate and be deposited on the surface of the substrate. Thereafter, the substrate 50 with the additional phosphorus ions implanted into the region where the openings 60 are performed is annealed. The annealing may be done in rapid thermal anneal (RTA) system, for example, at 1050° C. for a period of 30 seconds or, alternatively, in a furnace where the wafer is subjected to a temperature of approximately 850° C. for a period of approximately 30 minutes. This annealing will activate the high dose of dopants in the openings 60 on the front surface of the substrate 50. At the same time, if the wafer has not previously been subject to a furnace anneal as above-described in conjunction with FIG. 2, the phosphorus atoms implanted into the passivating layer 52 will also diffuse out of the passivating layer and into the substrate, but at a much lower dose concentration. This will simultaneously form the desired emitter structure wherein there is significant doping at the area where the contacts are to be formed with minimal doping between those regions, thus providing the desired emitter structure as above-described.

By reference now to FIG. 4, there is a flow chart showing the manner in which the device as shown in FIG. 3 is formed. As is illustrated, the silicon substrate is placed in an appropriate chamber 70 within which the passivation layer 52 is formed. Thereafter, in accordance with one embodiment of the present invention, an appropriate mask is screen printed onto the front surface of the substrate 50 as is well known in the prior art. The mask will be patterned in that it will have openings therein and the mask will be constructed of such material that it will block the penetration of the phosphorus ions into the upper surface of the substrate 50. After the mask is screen printed on as shown at 72, an appropriate plasma is generated in the chamber as shown at 74. When the plasma is generated, the P3i process is performed, thus causing ion implantation of phosphorus atoms, as a result of the plasma immersion, into the openings provided in the mask which has been screen printed on at 72. After the P3i process, the mask is removed by appropriate etching as is well known to those skilled in the art. As is shown at 76, thereafter the substrate, having been appropriately doped in the openings provided in the screen-printed mask, is placed in a belt furnace for annealling as shown at 78. When such occurs, the diffusion of the phosphorus atoms into the front surface of the substrate is accomplished as above-described. As above-described, if the passivation layer formed at 70 has been subjected to the P3i process, it includes phosphorus ions which have been implanted into the oxide passivation layer in a predetermined concentration as well as the highly-concentrated phosphorus ions which have been deposited through the P3i process after the mask has been screen printed on. The furnace anneal then will create the high and low doping regions such as shown at 58 and 56 in FIG. 3.

As an alternative embodiment after the passivation layer is formed as shown at 70 and if desired, subjected to the P3i process to obtain the appropriate doping therein, the masking pattern may be utilized by subjecting the passivation layer 52 to laser ablation to provide the openings 60 therein as shown at 80. After the openings 60 have been performed by the laser ablation, the substrate is then subjected to the P3i process as shown at 82. Subsequent to the deposition of the phosphorus ions in the openings 60, the substrate may then be subjected to an RTA 84 or the furnace anneal 78 or both in order to drive the phosphorus atoms into the substrate 50 to provide the above-referred to high low doping. Although not illustrated in FIG. 3, once the highly doped regions 58 are formed, an appropriate contact is applied as is well known to those skilled in the art.

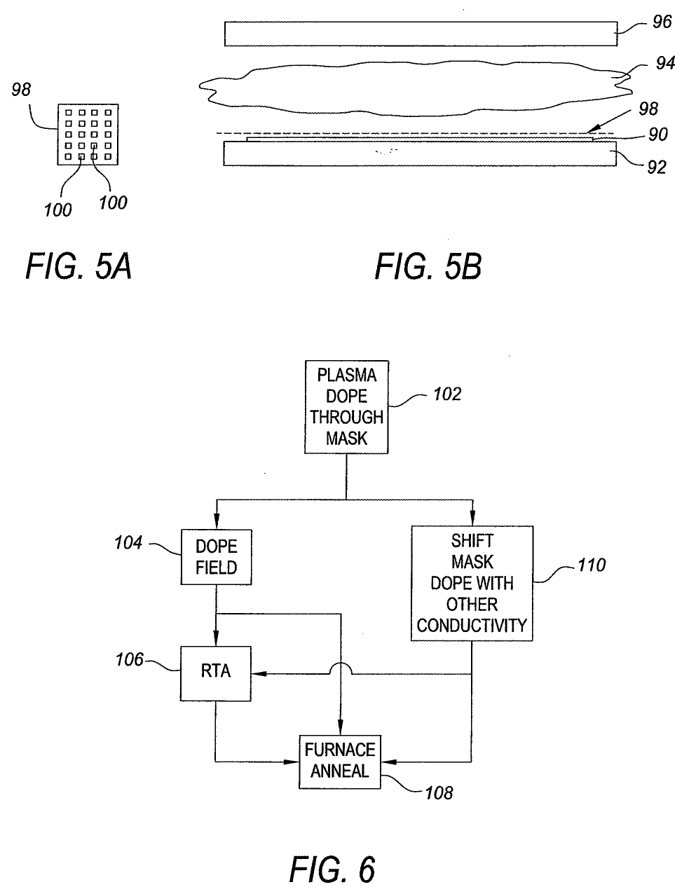

The P3i doping into the upper surface of the substrate may also be accomplished by the utilization of a physical mask which is placed above the wafer. This embodiment of the invention is illustrated in FIG. 5 to which reference is hereby made. As is therein shown, the substrate 90 is positioned on a bottom electrode 92 within a chamber wherein a plasma, as illustrated at 94, may be generated between the bottom electrode 92 and a top electrode 96, as is well known by those skilled in the art. A physical mask 98 is positioned over the top of the substrate 90 and includes a plurality of openings therein as shown at 100. Through generation of the plasma 94, the P3i process is carried out and the doping occurs only in the open regions 100. This type of process avoids patterning of the passivating SiO₂ layer. Subsequent to the P3i process being formed to implant the phosphorus ions, the substrate 90 is subjected to an annealing step as above-described to provide the high low areas of doping to provide the desired selective emitter. The physical mask may be made of any number of materials. In one embodiment, silicon is used, having been patterned using common micro-machining techniques such as through-hole etching or laser drilling.

As shown in FIG. 6 to which reference is hereby made, there is provided a flow chart showing the steps taken in accordance with the present invention utilizing the structure of FIG. 5. As is therein shown, plasma doping through a physical mask is accomplished at 102. The substrate with the doped field 104 is then subjected to the RTA 106 or the furnace anneal 108 or both in tandem as is illustrated. In accordance with an alternative embodiment, the mask 98 may be shifted to a different position and the upper surface of the substrate 90 doped with the opposite conductivity type to provide alternative regions of the N-type doping, if such is desired. Again, after the appropriate doping utilizing plasma, the wafer is then subjected to the RTA 106 or the furnace anneal 108 or both as may be desired.

There has been described a process for forming a selective emitter utilizing a plasma immersion ion implantation process to provide high and low doping regions in the surface of a silicon semiconductor substrate.

1. A method of selectively doping predetermined regions of a surface of a crystalline silicon body comprising:
forming a passivation layer on the surface, wherein the passivation layer comprises a dielectric material and a first amount of a doping atom;
patterning the passivation layer to define apertures therein;
plasma implanting a second amount of a doping atom into the patterned structure passivation layer; and
annealing the body.

2. (canceled)

3. The method of claim 1, wherein the passivation layer is patterned using laser ablation.

4. The method of claim 1, wherein the passivation layer is patterned using a mask and etching.

5. The method of claim 1, whereby, upon annealing, at least two (2) actively-doped regions are formed in the body with at least a portion of the doping atoms from at least one of the regions entering the body through out-diffusion from the patterned passivation layer.

6. The method of claim 1, in which the plasma-implanted second doping atoms include phosphorus.

7. The method of claim 1, in which the plasma-implanted second doping atoms include boron.

8. The method of claim 1, in which the plasma-implanted second doping atoms include arsenic.

9. A method for forming a selective emitter on a silicon solar cell including a substrate, the method comprising:
positioning a physical mask having a plurality of apertures formed at a first position over a surface of the substrate;
introducing a doping gas adjacent to the surface;
generating a plasma in the doping gas for plasma implanting doping ions of a first conductivity type through the plurality of apertures into regions of the substrate disposed below the plurality of apertures until a first dopant dose is reached; and
annealing the substrate with the doping ions disposed therein.

10-13. (canceled)

14. The method of claim 9, further comprising generating a plasma over the surface of the substrate, without the physical mask being positioned over the surface, and plasma implanting a doping ion into regions of the substrate until a second dopant dose is reached.

15. The method of claim 14, in which the first dopant dose and second dopant dose are different.

16. A method for forming a selective emitter on a silicon solar cell including a substrate, the method comprising:
forming a dielectric layer over a surface of the substrate, wherein the dielectric layer includes a first amount of a doping atom therein;
providing an antireflective layer over the dielectric layer;
forming apertures through the antireflective layer and the dielectric layer;
introducing a doping gas adjacent the surface;
generating a plasma in the doping gas for plasma implanting doping ions through the apertures and into the substrate; and
annealing the substrate with the doping ions disposed therein.

17. (canceled)

18. The method of claim 16, wherein the doping atoms in the dielectric layer have a first dose and the doping ions delivered into the substrate through the apertures have a second dose, the second dose being substantially greater than the first dose.

19. The method of claim 18, wherein the antireflective coating is silicon nitride.

20. The method of claim 18, wherein the apertures are formed by laser ablation.

21. The method of claim 20, wherein the dielectric layer, the laser ablation and the plasma doping are all formed within the same system.

22. The method of claim 1, wherein the passivation layer is annealed prior to patterning.

23. A method for forming a selective emitter on a silicon solar cell including a substrate, the method comprising:
forming a dielectric layer over a surface of the substrate, wherein the dielectric layer comprises a doping ion;
forming apertures in the dielectric layer;
introducing a doping gas adjacent to the surface;
generating a plasma in the doping gas to implant an amount of a doping ion through the apertures into regions of the substrate; and
annealing the substrate with the doping ions disposed therein.

24. The method of claim 23, wherein the doping ions in the dielectric layer have a first dose and the doping ions deposited through the apertures have a second dose, the second dose being substantially greater than the first dose.

25. The method of claim 1, wherein the first amount of the doping atoms in the patterned passivation layer is substantially less than the second amount of the doping atoms deposited through the apertures.

26. The method of claim 9, further comprising repositioning the physical mask to a second position above the surface of the substrate different from the first position, introducing a doping gas adjacent the surface, and generating a plasma in the doping gas for plasma implanting a second doping atom of a second conductivity type opposite to the first conductivity type through the apertures and into the substrate.
